(19) United States
(12) Patent Application Publication
(10) Pub. No.: US 2025/0351497 A1
(43) Pub. Date: Nov. 13, 2025

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Masaharu YAMAJI, Matsumoto-city (JP)

(73) Assignee: FUJI ELECTRIC CO., LTD., Kawasaki-shi (JP)

(21) Appl. No.: 19/091,177

(22) Filed: Mar. 26, 2025

(30) Foreign Application Priority Data
May 10, 2024 (JP) 2024-076975

(51) Int. Cl. H10D 62/60; H01L 21/225; H01L 21/304; H01L 21/324; H10D 62/10

(52) U.S. Cl. CPC H10D 62/60; H01L 21/2251; H01L 21/304; H01L 21/324; H10D 62/124

(57) ABSTRACT

A semiconductor device includes a semiconductor base body having: a semiconductor substrate of a first conductivity-type; and an epitaxial growth layer of the first conductivity-type provided on the semiconductor substrate, wherein the semiconductor base body has a thickness of 200 micrometers or greater and 400 micrometers or less, and a position of a peak concentration of oxygen in the semiconductor base body is located in a depth of 50 micrometers or greater and 250 micrometers or less from a top surface of the semiconductor base body.

### CROSS-REFERENCE TO RELATED APPLICATION

This application claims benefit of priority under 35 USC 119 based on Japanese Patent Application No. 2024-076975 filed on May 10, 2024, the entire contents of which are incorporated by reference herein.

### BACKGROUND OF THE INVENTION

### 1. Field of the Invention

The present disclosure relates to semiconductor devices and methods of manufacturing the same.

### 2. Description of the Related Art

JP2024-004663 A discloses that oxygen, which is mixed in silicon single crystals upon the growth of the silicon single crystals by a Czochralski (CZ) method, coheres by thermal treatment at a temperature of 350° C. or higher and 500° C. or lower to release electrons, so as to form an electrically active thermal donor.

JP5248741B2 discloses that oxygen contained in a silicon substrate is activated by annealing treatment at a temperature of 350° C. or higher and 500° C. or lower so as to be turned into a donor, and that oxygen atoms are outwardly diffused from the front surface side and the rear surface side of a silicon substrate by thermal treatment when a MOS structure is formed on the front surface side, so as to turn the oxygen to be a donor in a state in which an oxygen concentration is decreased in a depth of about 45 micrometers from each of the front surface and the rear surface.

JPH05-155682A discloses a magnetic field-applied Czochralski (MCZ) method.

As disclosed in JP2024-004663A and JP5248741B2, turning the oxygen in the silicon substrate to a donor may lead a conductivity to be inverted from p-type to n-type (N-inversion) in a deep region distant from the front surface of the silicon substrate or may lead to an increase in specific resistance, which could cause a decrease in breakdown voltage.

### SUMMARY OF THE INVENTION

In view of the foregoing problems, the present disclosure provides a semiconductor device and a method of manufacturing the same capable of avoiding a decrease in breakdown voltage caused in association with a shift of oxygen in a silicon substrate to a donor.

An aspect of the present disclosure inheres in a semiconductor device including a semiconductor base body having: a semiconductor substrate of a first conductivity-type; and an epitaxial growth layer of the first conductivity-type provided on the semiconductor substrate, wherein the semiconductor base body has a thickness of 200 micrometers or greater and 400 micrometers or less, and a position of a peak concentration of oxygen in the semiconductor base body is located in a depth of 50 micrometers or greater and 250 micrometers or less from a top surface of the semiconductor base body.

Another aspect of the present disclosure inheres in a method of manufacturing a semiconductor device, including: preparing a semiconductor base body having a thickness of 200 micrometers or greater and 400 micrometers or less and including a semiconductor substrate of a first conductivity-type and an epitaxial growth layer of the first conductivity-type provided on the semiconductor substrate; decreasing a peak concentration of oxygen in the semiconductor base body by outwardly difussing the oxygen toward a top surface and a bottom surface of the semiconductor base body by first thermal treatment; and turning the oxygen in the semiconductor base body into a donor by second thermal treatment with the peak concentration of the oxygen in the semiconductor base body decreased.

### BRIEF DESCRIPTION OF THE DRAWINGS

FIG. 1 is a cross-sectional view illustrating a semiconductor device according to a first embodiment;

FIG. 2 is a cross-sectional process view illustrating a method of manufacturing the semiconductor device according to the first embodiment;

FIG. 3 is a cross-sectional process view continued from FIG. 2, illustrating the method of manufacturing the semiconductor device according to the first embodiment;

FIG. 4 is a cross-sectional process view continued from FIG. 3, illustrating the method of manufacturing the semiconductor device according to the first embodiment;

FIG. 5 is a cross-sectional process view continued from FIG. 4, illustrating the method of manufacturing the semiconductor device according to the first embodiment;

FIG. 6 is a cross-sectional process view continued from FIG. 5, illustrating the method of manufacturing the semiconductor device according to the first embodiment;

FIG. 7 is a cross-sectional process view continued from FIG. 6, illustrating the method of manufacturing the semiconductor device according to the first embodiment;

FIG. 8 is a flowchart showing an example of a thermal history of the method of manufacturing the semiconductor device according to the first embodiment;

FIG. 9 is a table showing an example of conditions for thermal treatment used in oxidation processes and diffusion processes shown in FIG. 8;

FIG. 10 is a table showing an example of conditions for thermal treatment used in annealing processes shown in FIG. 8;

FIG. 11 is a cross-sectional view illustrating a semiconductor device of a comparative example;

FIG. 12 is a graph showing a profile of an oxygen concentration in the semiconductor device of the comparative example;

FIG. 13 is a graph showing a profile of a carrier concentration in the semiconductor device of the comparative example;

FIG. 14 is a graph showing a profile of an oxygen concentration in the semiconductor device according to the first embodiment;

FIG. 15 is a graph showing a profile of a carrier concentration in the semiconductor device according to the first embodiment;

FIG. 16 is a cross-sectional process view illustrating a method of manufacturing a semiconductor device according to a second embodiment;

FIG. 17 is a cross-sectional process view continued from FIG. 16, illustrating the method of manufacturing the semiconductor device according to the second embodiment;

FIG. 18 is a cross-sectional view illustrating a semiconductor device according to a third embodiment; and

FIG. 19 is a cross-sectional view illustrating a semiconductor device according to a fourth embodiment.

### DETAILED DESCRIPTION

With reference to the drawings, first to fourth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to fourth embodiments described below merely illustrate schematically devices and methods for specifying and giving shapes to the technical idea of the present disclosure, and the span of the technical idea is not limited to materials, shapes, structures, and relative positions of elements described herein.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

### <Configuration of Semiconductor Device>

A semiconductor device according to a first embodiment is illustrated below with a high-voltage integrated circuit (HVIC) of a 1200-V guarantee class that is a high-voltage power IC. The HVIC drives a high-potential-side switching element and a low-potential-side switching element (not illustrated) for one phase of a bridge circuit for power conversion.

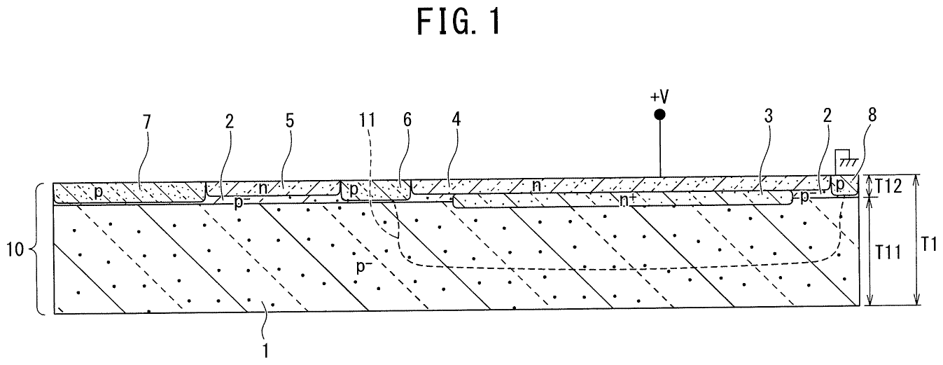

As illustrated in FIG. 1, the semiconductor device according to the first embodiment includes a semiconductor base body (also referred to below as a “buried epitaxial substrate”) 10 including silicon (Si). A thickness T1 of the semiconductor base body 10 is set in a range of about 200 micrometers or greater and 400 micrometers or less, for example, or may be in a range of about 200 micrometers or greater and 350 micrometers or less, in a range of about 200 micrometers or greater and 300 micrometers or less, or in a range of about 200 micrometers or greater and 250 micrometers or less.

Oxygen (interstitial oxygen) mixed in the semiconductor base body 10 during the manufacturing process is contained between lattices of silicon (Si) included in the semiconductor base body 10. An oxygen concentration in the semiconductor base body 10 is set in a range of about 1×10¹⁷ atoms/cm³ or higher and lower than 1×10¹⁸ atoms/cm³, or may be in a range of about 3×10¹⁷ atoms/cm³ or higher and lower than 1×10¹⁸ atoms/cm³. The oxygen concentration as used herein is an interstitial oxygen concentration [Oi] obtained by Fourier transform infrared spectroscopy (FTIR) prescribed by ASTM F121 (1979). A position of a peak concentration of oxygen in the semiconductor base body 10 is located in a depth of about 50 micrometers or greater and 250 micrometers or less from the top surface of the semiconductor base body 10.

The semiconductor base body 10 includes a semiconductor substrate 1 of a first conductivity-type (p″-type), and an epitaxial growth layer 2 of the first conductivity-type (p-type) provided on the top surface of the semiconductor substrate 1. The semiconductor substrate 1 is a silicon (Si) substrate grown by a Czochralski (CZ) method. A thickness T11 of the semiconductor substrate 1 is set in a range of about 180 micrometers or greater and 395 micrometers or less, for example. The semiconductor substrate 1 has a p-type impurity concentration in a range of about 1×10¹³ cm⁻³ or higher and 2×10¹⁵ cm⁻³ or lower, for example. The p-type impurity concentration of the semiconductor substrate 1 has a concentration gradient in the thickness direction of the semiconductor substrate 1, which has the minimum value at a position corresponding to the peak concentration of oxygen in the semiconductor base body 10.

The epitaxial growth layer 2 is a semiconductor layer including silicon (Si). A thickness T12 of the epitaxial growth layer 2 is set in a range of about 5 micrometers or greater and 20 micrometers or less, for example. The epitaxial growth layer 2 has a p-type impurity concentration in a range of about 1×10¹³ cm⁻³ or higher and 2×10¹⁵ cm⁻³ or lower, for example. The impurity concentration of the epitaxial growth layer 2 may be substantially the same as, higher than, or lower than the impurity concentration of the semiconductor substrate 1.

A buried layer 3 of a second conductivity-type (n⁺-type) is locally (partly) provided between the semiconductor substrate 1 and the epitaxial growth layer 2. The buried layer 3 is a diffusion layer obtained by ion implantation of n-type impurities such as antimony (Sb), phosphorus (P), and arsenic (As). The buried layer 3 is located in a depth of about 5 micrometers or greater and 20 micrometers or less from the top surface of the semiconductor base body 10. The buried layer 3 has a function of suppressing a wrong operation or damage caused by a parasitic operation induced by a negative voltage surge in a high-side power-source voltage line or the like.

Semiconductor regions (well regions) 4 and 5 of n-type each having a lower impurity concentration than the buried layer 3 are provided separately from each other on the top surface side of the epitaxial growth layer 2. The semiconductor regions 4 and 5 are each a diffusion layer obtained by ion implantation of n-type impurities such as phosphorus (P) and arsenic (As).

The semiconductor region 4 implements a high-potential-side circuit (a high-side circuit). A potential (VB potential) is applied to the semiconductor region 4 from a high-potential-side power source. The bottom surface of the semiconductor region 4 is in contact with the buried layer 3. The semiconductor region 5 implements a low-potential-side circuit (a low-side circuit). A potential (VCC potential) is applied to the semiconductor region 5 from a low-potential-side power source. Although not illustrated in FIG. 1, the respective semiconductor regions 4 and 5 are provided with several kinds of semiconductor elements such as transistors implementing a CMOS circuit.

Semiconductor regions 6, 7, and 8 of p-type each having a higher impurity concentration than the epitaxial growth layer 2 are provided on the top surface side of the epitaxial growth layer 2. The semiconductor regions 6, 7, and 8 are each a diffusion layer obtained by ion implantation of p-type impurities such as boron (B). A ground potential (GND potential) is applied to the semiconductor regions 6, 7, and 8. The semiconductor regions 6, 7, and 8 are provided to be in contact with the respective semiconductor regions 4 and 5 so as to surround the circumferences of the semiconductor regions 4 and 5. The semiconductor regions 6, 7, and 8 may be an integrated region connected together on the front side or on the back side of the sheet of FIG. 1.

Although not illustrated in FIG. 1, several kinds of elements, such as a field insulating film, an interlayer insulating film, a passivation film, and gate insulating films, electrodes, and wires of the respective semiconductor elements, are provided on the top surface side of the semiconductor base body 10.

### <Method of Manufacturing Semiconductor Device>

An example of a method of manufacturing the semiconductor device according to the first embodiment illustrated in FIG. 1 is described below.

First, a substrate production process of producing the semiconductor base body 10 is executed. The substrate production process grows silicon single crystals, by the CZ method, having a specific resistance in a range of about 200 Ω·cm or higher and 300 Ω·cm or lower and an oxygen concentration in a range of about 1×10¹⁸ atoms/cm³ or higher and 1.3×10¹⁸ atoms/cm³ or lower. Oxygen is mixed in the silicon single crystals because a quartz crucible is used in this process. The mixed oxygen is provided between silicon lattices.

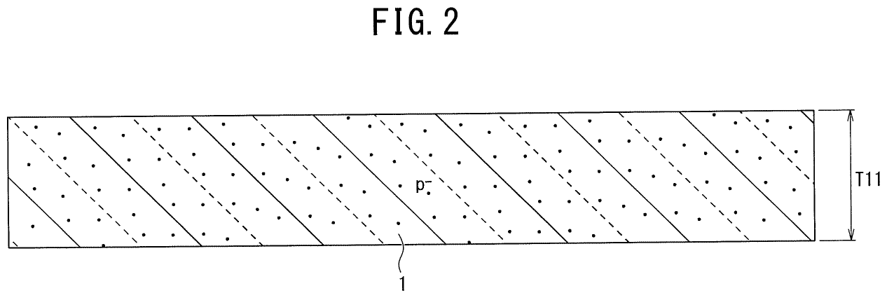

Next, the silicon single crystals grown by the CZ method are sliced so that the p-type semiconductor substrate 1 is cut out with the thickness T11 in the range of about 180 micrometers or greater and 395 micrometers or less, as illustrated in FIG. 2.

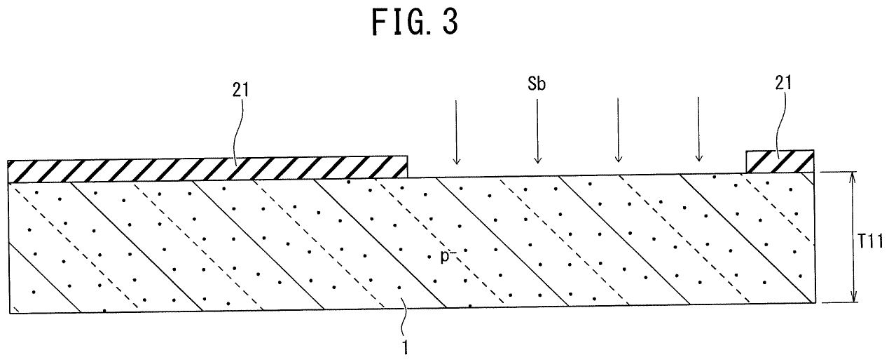

Next, a photoresist film 21 is applied to the top surface of the semiconductor substrate 1 (refer to FIG. 3), and is delineated by photolithography. Using the delineated photoresist film 21 as a mask for ion implantation, n-type impurity ions such as antimony (Sb) are implanted from above into the top surface of the semiconductor substrate 1. The photoresist film 21 is then removed. Instead of the photoresist film 21, an oxide film may be applied and delineated so as to be used as a mask for ion implantation.

Next, the p″-type epitaxial growth layer with the thickness T12 in the range of about 5 micrometers or greater and 10 micrometers or less is grown on the top surface of the semiconductor substrate 1. At this point, the n-type impurity ions implanted into the semiconductor substrate 1 are activated and diffused, so as to form the n⁺-type buried layer 3 between the semiconductor substrate 1 and the epitaxial growth layer 2. This process produces (prepares) the semiconductor base body (the buried epitaxial substrate) 10 including the semiconductor substrate 1, the epitaxial growth layer 2, and the buried layer 3, so as to finish the substrate production process. To deal with wafer chipping during the IC manufacturing process, wafer edges may be subjected to chamfering processing such as beveling.

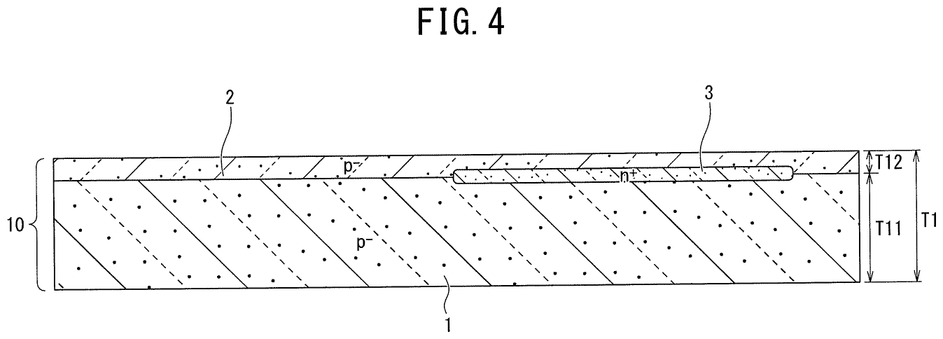

As illustrated in FIG. 4, the thickness T1 of the semiconductor base body 10 corresponds to the total thickness of the thickness T11 of the semiconductor substrate 1 in the range of about 180 micrometers or greater and 395 micrometers or less and the thickness T12 of the epitaxial growth layer 2 in the range of about 5 micrometers or greater and 20 micrometers or less. The thickness T1 of the semiconductor base body 10 is set in a range of about 200 micrometers or greater and 400 micrometers or less, or may be in a range of about 200 micrometers or greater and 350 micrometers or less, in a range of about 200 micrometers or greater and 300 micrometers or less, or in a range of about 200 micrometers or greater and 250 micrometers or less, for example.

Setting the thickness T1 of the semiconductor base body 10 to about 400 micrometers or less facilitates outward diffusion of oxygen (described in detail below) into a deep region in the semiconductor base body 10 by the following thermal treatment included in the manufacturing process. In order to exhibit the outward diffusion of oxygen into a deep region in the semiconductor base body 10, the thickness T1 of the semiconductor base body 10 is preferably set to about 350 micrometers or less, more preferably set to about 300 micrometers or less, and even more preferably set to about 250 micrometers or less.

Also, setting the thickness T1 of the semiconductor base body 10 to about 200 micrometers or greater can suppress a warp or cracks caused in the semiconductor substrate 1 during the following processes included in the manufacturing process, such as a process applied with thermal stress such as thermal treatment and a conveyance process. Further, as illustrated in FIG. 1, a depletion layer 11, when extending toward the semiconductor substrate 1 from the semiconductor region 4 and the buried region 3 so as to have a width in a range of about 100 micrometers or greater and 200 micrometers or less upon the application of high voltage +V to the HVIC of the 1200-V guarantee class, can be prevented from reaching the bottom surface of the semiconductor substrate 1.

Further, the thickness T1 of the semiconductor base body 10 can be increased as the diameter of the semiconductor base body 10 is larger. The thickness T1 of the semiconductor base body 10 may be set in a range of about 200 micrometers or greater and 400 micrometers or less when the diameter of the semiconductor base body 10 is 150 millimeters, and may be set in a range of about 300 micrometers or greater and 400 micrometers or less when the diameter of the semiconductor base body 10 is 200 millimeters.

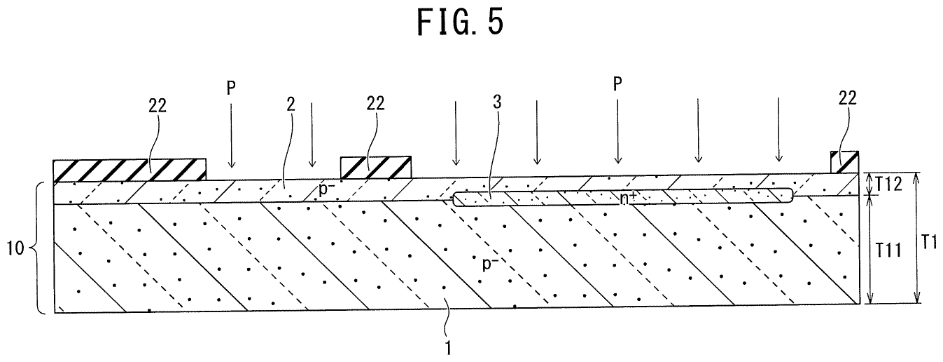

Next, the semiconductor base body 10 produced in the substrate production process is put into a production line of a front-end-of-line (FEOL) process that is the upstream process of the IC manufacturing process. A photoresist film 22 is first applied to the top surface of the epitaxial growth layer 2 (refer to FIG. 5), and is delineated by photolithography. Using the delineated photoresist film 22 as a mask for ion implantation, n-type impurity ions such as phosphorus (P) are implanted from above into the top surface of the epitaxial growth layer 2, as illustrated in FIG. 5. The photoresist film 22 is then removed. Instead of the photoresist film 22, an oxide film may be applied and delineated so as to be used as a mask for ion implantation.

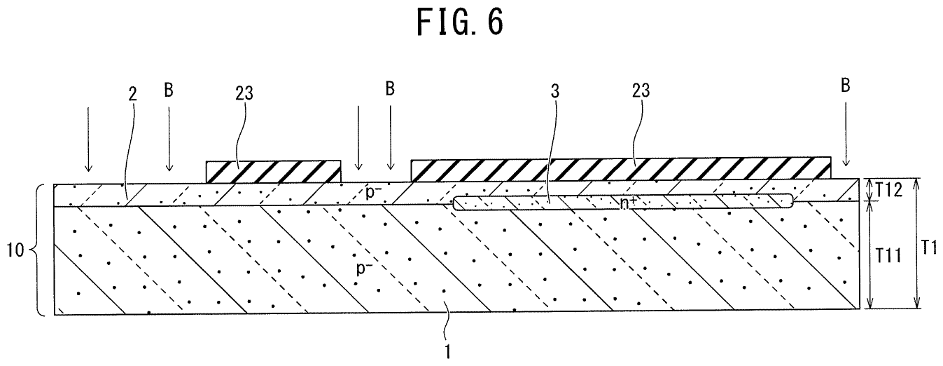

Next, a photoresist film 23 is applied to the top surface of the epitaxial growth layer 2 (refer to FIG. 6), and is delineated by photolithography. Using the delineated photoresist film 23 as a mask for ion implantation, p-type impurity ions such as boron (B) are implanted from above into the top surface of the epitaxial growth layer 2, as illustrated in FIG. 6. The photoresist film 23 is then removed. Instead of the photoresist film 23, an oxide film may be applied and delineated so as to be used as a mask for ion implantation.

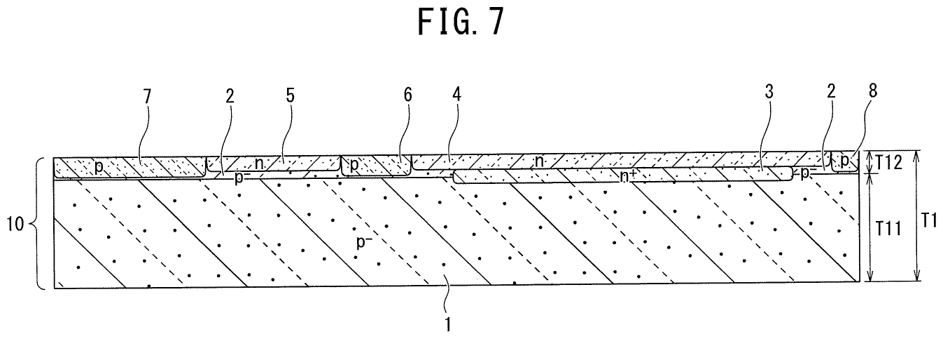

Next, the n-type impurity ions and the p-type impurity ions implanted into the epitaxial growth layer 2 are activated by thermal treatment. This process forms the n-type semiconductor regions 4 and 5 and the p-type semiconductor regions 6, 7, and 8 on the top surface side of the epitaxial growth layer 2, as illustrated in FIG. 7. Although not illustrated, the FEOL may further form additional semiconductor regions other than the semiconductor regions 4 to 8. The FEOL is thus finished.

Next, a back-end-of-line (BEOL) process that is the upstream process of the IC manufacturing process is executed. The BEOL forms various kinds of elements such as an interlayer insulating film, a passivation film, electrodes, and wires are provided on the top surface side of the semiconductor base body 10. Thereafter, the semiconductor base body 10 is diced so as to be divided into a plurality of chips. The semiconductor device as illustrated in FIG. 1 is thus completed.

### <Oxygen Mixed in Silicon Single Crystals>

The oxygen mixed in the silicon single crystals is described below. High-voltage power ICs conventionally use a semiconductor base body with high-specific-resistance specifications of 100 (2·cm or greater in order to achieve high noise tolerance. A p-type semiconductor substrate implementing the semiconductor base body is typically grown by a MCZ method that enables manufacture at a low oxygen concentration in order not to lead to an inversion of a conductivity from p-type to n-type (N-inversion) or not to lead to an increase in specific resistance of the substrate caused in association with a shift of oxygen to a donor under a condition of temperature in a range of 350° C. or higher and 500° C. or lower during the IC manufacturing process.

When the semiconductor substrate is grown by the CZ method, an eddy current tends to be caused in a liquid phase, and a shape at a solid-liquid interface, a temperature gradient, and a uniformity in distribution of an oxygen concentration are difficult to regulate. A surface of a quartz crucible is melted in silicon, and oxygen is thus inevitably mixed in the liquid phase as an impurity and is combined with silicon to produce stack-layer defects, which leads interstitial oxygen to be distributed at a relatively high concentration.

In contrast, the growth by the MCZ method can effectively suppress thermal convention, can evenly diffuse impurity ions contained, and can reduce fusion of oxygen atoms from the quartz crucible, so as to decrease the oxygen concentration and thus improve the crystal quality. Meanwhile, the oxygen at the same time has the advantage of capturing contamination of impurities (gettering) once precipitating during thermal treatment of the device to produce bulk micro defects (BMD). Further, crystals having a relatively high oxygen concentration and capable of allowing the wafer to keep an internal gettering ability also have some advantages and demand in order to deal with heavy metal contamination in a diffusion furnace.

Another crystal growth method at a low oxygen concentration is a floating zone (FZ) method that heats and melts lower parts of polycrystalline silicon rods and moves a furnace downward while supporting a liquid phase with surface tension so as to grow single crystals. This method can grow the entire length of crystals at constant high specific resistance through continuous supply by use of a gas dope, but it is difficult to achieve an increase in diameter of 200 millimeters or greater. A FZ substrate has the characteristics not suitable for a buried epitaxial substrate because the FZ substrate has substantially no oxygen atoms that have an effect of avoiding a slip dislocation during a growth process, and slip thus tends to be caused in a wafer when the crystals are epitaxially grown on the FZ substrate.

The crystals, if having a low oxygen concentration of less than 1×10¹⁷ atoms/cm³, have a problem with the gettering ability or slipping, and, if having a high oxygen concentration of 1×10¹⁸ atoms/cm³ or higher by the CZ method, lead to an N-inversion or an increase in specific resistance (>300 Ω·cm) in the p-type semiconductor substrate because of an influence of a thermal donor by thermal treatment at a temperature of 350° C. or higher and 500° C. or lower. Such oxygen concentrations can cause a defect or variation in breakdown voltage in the high-voltage power IC and are thus not preferable.

The N-inversion or the increase in the specific resistance in the p-type semiconductor substrate decreases the oxygen concentration by outward diffusion of the oxygen atoms through some processes such as a high-temperature diffusion process and an annealing process included in the manufacturing process up to a depth of 50 micrometers or greater and 200 micrometers or less from the top and bottom surfaces of the crystals. While the N-inversion is not caused on the top surface side and the bottom surface side of the crystals, the N-inversion or the increase in the specific resistance is typically caused in a region with a depth of 100 micrometers or greater and 500 micrometers or less from the top and bottom surfaces of the crystals when a wafer thickness is 600 micrometers, for example. A depletion layer can extend to 100 micrometers or more toward the p-type semiconductor substrate when a high voltage is applied to a high-voltage device of a high-voltage power IC, and thus serve as a component of a leak current through a chip side wall if reaching the N-inversion region, which would lead to a defect in breakdown voltage.

In view of this, the buried epitaxial substrate provided with the p-type semiconductor substrate grown by the MCZ method, which is suitable for a low oxygen concentration, is conventionally used for the high-voltage power IC and the like.

The MCZ method, which uses a CZ furnace surrounded by magnets, is divided into three methods regarding magnetic application, which are a lateral magnetic field method, a vertical magnetic field method, and a cusp-type magnetic field method. While the inside of the magnets is subjected to magnetic shielding depending on risks, even such magnets are inevitably used under the condition in which magnetic-field leakage is caused to some extent because of an aspect of weight of a magnetic shielding material. Some measures for circumferential magnetic force are thus required to be taken depending on the intensity of the magnetic field leakage. The magnetic field leakage has an influence on electronic devices, and can further cause damage to the magnets because some force is applied to the magnets themselves if any magnetic material is present along the circumference. Further, dimensions or materials of steel frames of floors and walls around the circumference of an installed location or installation intervals of apparatuses also need to be taken into consideration even at an initial stage of zone designing of a CZ compartment. The method using such magnets is further divided into two methods, which are a normal conducting method and a superconducting method. The superconducting method, which is a leading method, needs to execute cooling treatment by use of liquid helium and a refrigerator, and can be a manufacturing method requiring higher costs than the conventional CZ method in view of some aspects such as economic issues (initial investment costs, running costs, maintenance costs, and the like) and public utilities (such as electric power, cooling water, and the like). The CZ crystals thus actually contribute to higher production and supplying performance for crystal manufacturers.

### <Oxygen Outward Diffusion and Shift to Donor>

The outward diffusion and a shift to a donor (a thermal donor) regarding the oxygen in the semiconductor base body 10 in the method of manufacturing the semiconductor device according to the first embodiment are described below.

The method of manufacturing the semiconductor device according to the first embodiment includes a process of leading the oxygen in the semiconductor base body 10 to be outwardly diffused toward the top surface and the bottom surface of the semiconductor base body 10 by the thermal treatment at a temperature in a range of about 1000° C. or higher and 1200° C. or lower (referred to below as “first thermal treatment”) so as to decrease the peak concentration of the oxygen in the semiconductor base body 10. The time required for the first thermal treatment is in a range of about one hour or longer and 50 hours or shorter, for example.

The first thermal treatment corresponds to the thermal treatment executed in the substrate production process or the FEOL, for example. The thermal treatment in the FEOL corresponds to thermal treatment in high-temperature drive treatment or annealing treatment. The first thermal treatment may be either thermal treatment including a single process or thermal treatment including plural processes. The plural processes corresponding to the first thermal treatment may be either continuous processes or separated processes. The time required for the first thermal treatment may be either the time corresponding to a single process or the total time corresponding to plural processes. For example, the thermal treatment in the diffusion process as illustrated in FIG. 7 corresponds to at least a part of the first thermal treatment.

The outward diffusion of the oxygen in the semiconductor base body 10 in the first thermal treatment easily leads the oxygen to come out toward the top surface and the bottom surface of the semiconductor base body 10 in a region of about 100 micrometers or greater and 200 micrometers or less from the top surface and the bottom surface. The method of manufacturing the semiconductor device according to the first embodiment processes the semiconductor base body 10 to have the thickness T1 as thin as about 200 micrometers or greater and 400 micrometers or less, so as to easily lead the oxygen also present around the middle of the thickness of the semiconductor base body 10 to come out toward the top surface and the bottom surface during the outward diffusion of the oxygen in the semiconductor base body 10. The peak concentration of the oxygen in the semiconductor base body 10 thus can be decreased to less than 1×10¹⁸ atoms/cm³. The oxygen in the semiconductor base body 10 is outwardly diffused substantially evenly (substantially symmetrically) toward the upper or lower surface. The position of the peak concentration of the oxygen in the semiconductor base body 10 is therefore located substantially in the middle of the thickness of the semiconductor base body 10.

The method of manufacturing the semiconductor device according to the first embodiment further includes a process of leading the oxygen in the semiconductor base body 10 to be a donor (a thermal donor) by executing thermal treatment at a temperature in a range of about 350° C. or higher and 500° C. or lower (referred to below as “second thermal treatment”), which is lower than that in the first thermal treatment, in the state of decreasing the peak concentration of the oxygen in the semiconductor base body 10 by the outward diffusion of the oxygen by the first thermal treatment. The time required for the second thermal treatment is in a range of about one minute or longer and one hour or shorter, for example.

The second thermal treatment corresponds to hydrogen annealing in the BEOL or the like, bake hardening treatment for a spin-on-glass (SOG) film, or thermal treatment in plasma chemical vapor deposition (CVD) or the like. The second thermal treatment may be either thermal treatment including a single process or thermal treatment including plural processes. The plural processes corresponding to the second thermal treatment may be either continuous processes or separated processes. The time required for the second thermal treatment may be either the time corresponding to a single process or the total time corresponding to plural processes.

The oxygen in the semiconductor base body 10 itself is electrically inactive, but is condensed by the second thermal treatment to release electrons so as to form an electrically active thermal donor. The thermal donor is an aggregate of several to several tens of oxygen atoms. Not all but some oxygen in the semiconductor base body 10 is turned into a thermal donor. The density of the oxygen turned into a thermal donor is higher as the oxygen concentration in the semiconductor base body 10 is higher. The method of manufacturing the semiconductor device according to the first embodiment turns the oxygen into a thermal donor in the state in which the peak concentration of the oxygen is decreased to less than 1×10¹⁸ atoms/cm³, so as to suppress a decrease in breakdown voltage caused in association with the shift of the oxygen in the semiconductor base body 10 to a thermal donor.

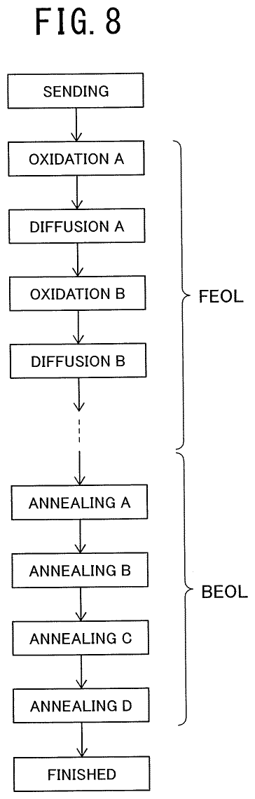

FIG. 8 is a flowchart showing an example of a thermal history of the IC manufacturing process after the substrate production process in the method of manufacturing the semiconductor device according to the first embodiment. As shown in FIG. 8, Oxidation A as an oxidation process, Diffusion A as a diffusion process, Oxidation B as an oxidation process, Diffusion B as a diffusion process, and more subsequent processes, for example, are executed in the FEOL that is the upstream process of the IC manufacturing process. The respective oxidation processes may be a process of forming an oxidation film used as a mask for ion implantation or a mask for etching. The respective diffusion processes may be a process of activating and then diffusing implanted p-type impurity ions or n-type impurity ions. The number of the oxidation processes and the diffusion processes included in the FEOL can be determined as appropriate. Further, Annealing A to D each as an annealing process are executed in the BEOL that is the upstream process of the IC manufacturing process. The number of the annealing processes included in the BEOL can be determined as appropriate.

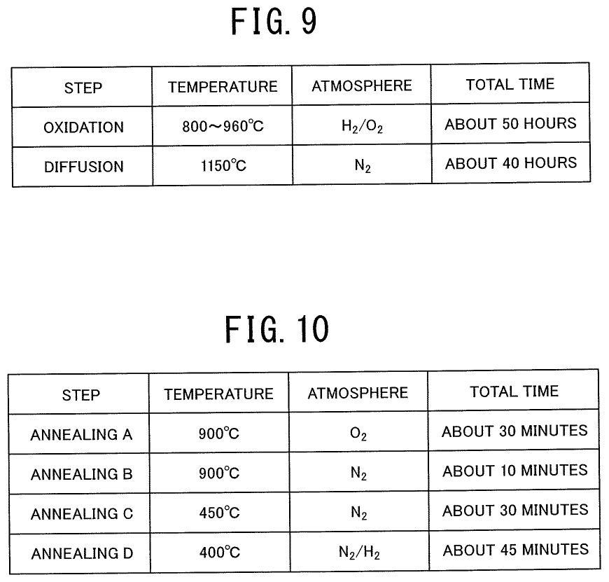

FIG. 9 shows an example of the conditions for the oxidation processes such as Oxidation A and Oxidation B in the FEOL and the conditions for the diffusion processes such as Diffusion A and Diffusion B in the FEOL shown in FIG. 8. The term “total time” shown in FIG. 9 refers to a time during which a target temperature is kept, excluding a temperature-increasing time that a temperature needs to reach the target temperature and a temperature-decreasing time during which the temperature is decreasing from the target temperature. As shown in FIG. 9, each oxidation process is executed at a temperature in a range of about 800° C. or higher and 900° C. or lower in a hydrogen (H₂) atmosphere or an oxygen (O₂) atmosphere for about 50 hours. Each diffusion process is executed at a temperature of about 1150° C. in a nitrogen (N₂) atmosphere for about 40 hours. At least the diffusion processes of the respective oxidation processes and diffusion processes shown in FIG. 9 correspond to the first thermal treatment.

FIG. 10 shows an example of the conditions for Annealing A to D shown in FIG. 8. The term “total time” shown in FIG. 10 refers to a time during which a target temperature is kept, excluding a temperature-increasing time that a temperature needs to reach the target temperature and a temperature-decreasing time during which the temperature is decreasing from the target temperature. Annealing A is executed at a temperature of 900° C. in an oxygen (O₂) atmosphere for about 30 minutes. Annealing B is executed at a temperature of 900° C. in a nitrogen (N₂) atmosphere for about 10 minutes. Annealing C is executed at a temperature of 450° C. in a nitrogen (N₂) atmosphere for about 30 minutes. Annealing D is executed at a temperature of 400° C. in a nitrogen (N₂) atmosphere or a hydrogen (H₂) atmosphere for about 45 minutes. At least Annealing C and D of Annealing A to D shown in FIG. 10 correspond to the second thermal treatment.

As described above, the method of manufacturing the semiconductor device according to the first embodiment includes the process of preparing the semiconductor base body 10 with the thickness in the range of 200 micrometers or greater and 400 micrometers or less including the semiconductor substrate 1 and the epitaxial growth layer 2 provided on the semiconductor substrate 1, the process of outwardly diffusing oxygen in the semiconductor base body 10 toward the top surface and the bottom surface by the first thermal treatment so as to decrease the peak concentration of the oxygen in the semiconductor base body 10, and the process of turning the oxygen in the semiconductor base body 10 into a donor by the second thermal treatment with the peak concentration of the oxygen in the semiconductor base body 10 decreased.

### COMPARATIVE EXAMPLE

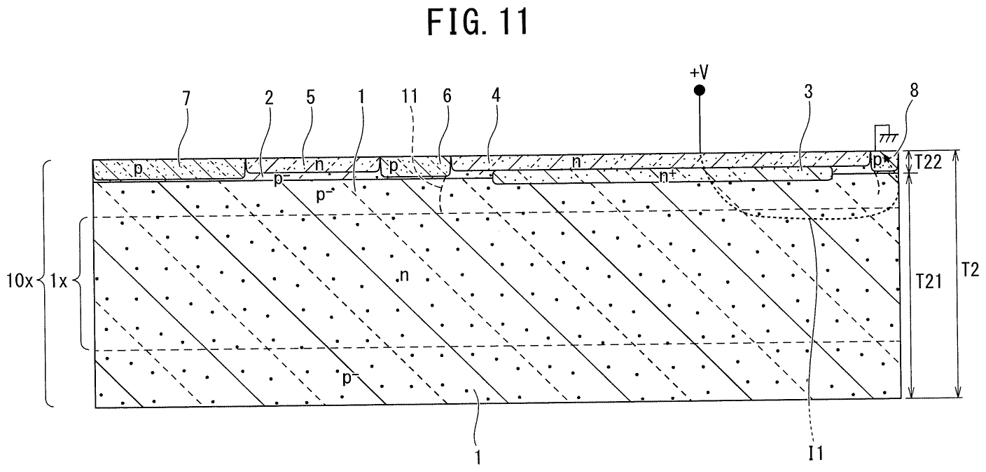

A semiconductor device of a comparative example and a method of manufacturing the same is described below. As illustrated in FIG. 11, the semiconductor device of the comparative example differs from the semiconductor device according to the first embodiment in that the semiconductor base body 10x has a thickness T2 as thick as 600 micrometers or greater. The thickness T2 of the semiconductor base body 10x is 625 micrometers when the diameter of the semiconductor base body 10x is 150 millimeters, and 725 micrometers when the diameter is 200 millimeters. Alternatively, the semiconductor substrate 1 may be ground from the bottom surface so that the thickness T2 of the semiconductor base body 10x is decreased to about 300 micrometers.

The method of manufacturing the semiconductor device of the comparative example slices up the silicon single crystals grown by the CZ method to have a thickness of 600 micrometers or greater that is greater than that obtained by the method of manufacturing the semiconductor device according to the first embodiment so as to cut out the p-type semiconductor substrate 1. The other steps of the method of manufacturing the semiconductor device of the comparative example are substantially the same as those of the method of manufacturing the semiconductor device according to the first embodiment.

The method of manufacturing the semiconductor device of the comparative example includes the process of outwardly diffusing the oxygen in the semiconductor base body 10x by the first thermal treatment, and the process of turning the oxygen in the semiconductor base body 10x into a thermal donor by the second thermal treatment, as in the case of the method of manufacturing the semiconductor device according to the first embodiment. However, the semiconductor device of the comparative example impedes the outward diffusion of the oxygen present in a deep region of the semiconductor base body 10x, since the semiconductor base body 10x has the thickness as thick as 600 micrometers or greater.

The semiconductor device manufactured by the method of the comparative example is therefore provided with an N-inversion region 1x in which the conductivity is inverted from p-type to n-type in a region with a depth of about 100 micrometers or greater and 500 micrometers or less from the top surface and the bottom surface of the semiconductor base body 10x, as illustrated in FIG. 11. If high voltage +V are applied to the semiconductor device, the depletion layer 11 would reach the N-inversion region 1x, causing a leakage current I1 as schematically indicated by the arrow in FIG. 11. Further, since the volume of the depletion layer 11 increases in association with the increase in the specific resistance of the semiconductor base body 10x, a junction leakage current at high temperature increases, which leads to a breakdown-voltage decreasing mode.

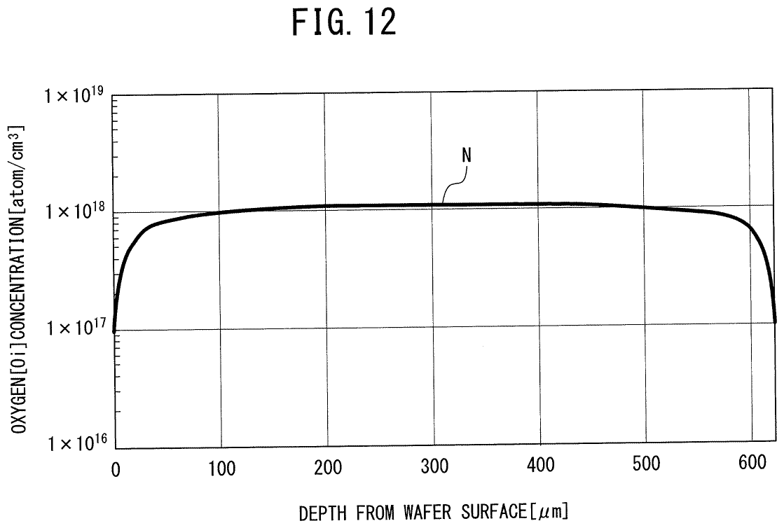

FIG. 12 is a profile of an oxygen concentration in the semiconductor base body 10x of the semiconductor device of the comparative example when the thickness T2 of the semiconductor base body 10x is set to 625 micrometers. As shown in FIG. 12, a position of a peak concentration N of the oxygen in the semiconductor base body 10x is about 310 micrometers below from the top surface of substantially the middle of the semiconductor base body 10x in the thickness direction. The peak concentration N of the oxygen is higher than 1×10¹⁸ atoms/cm³.

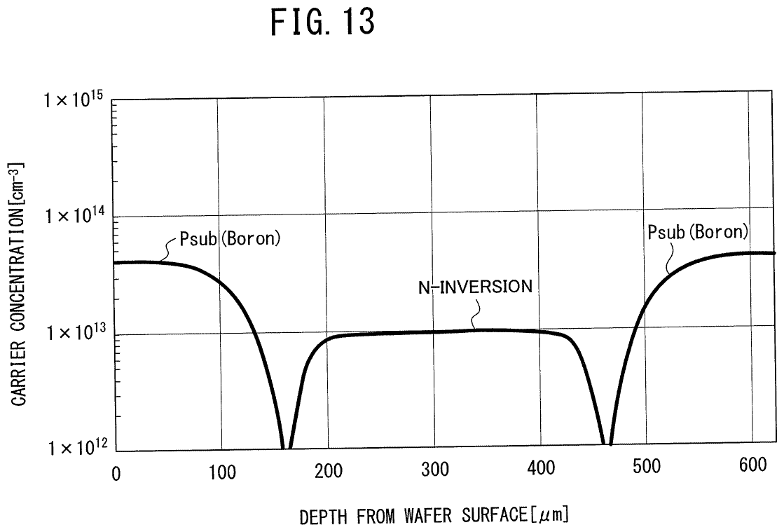

FIG. 13 is a profile of a carrier concentration in the thickness direction of the semiconductor base body 10x of the semiconductor device of the comparative example when the thickness T2 of the semiconductor base body 10x is set to 625 micrometers. The carrier concentration as used herein can be obtained by SR measurement. The conductivity in the profile as indicated by “Psub (Boron)” in a range of about 160 micrometers from the top surface and the bottom surface of the semiconductor base body 10x is p-type. The part of the semiconductor base body 10x in the middle in the thickness direction indicated by “N-inversion” is in a state in which the p-type impurity ions are offset by the oxygen turned to a donor in the semiconductor base body 10x so that the conductivity is inverted from p-type to n-type (N-inversion).

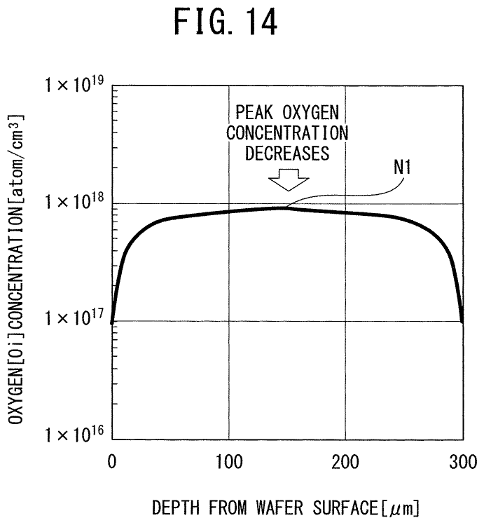

FIG. 14 is a profile of an oxygen concentration in the semiconductor base body 10 of the semiconductor device according to the first embodiment when the thickness T1 of the semiconductor base body 10 is set to 300 micrometers. A position of a peak concentration N1 of the oxygen in the semiconductor base body 10 is about 150 micrometers from the top surface of the semiconductor body 10 that is substantially in the middle of the semiconductor base body 10 in the thickness direction. The peak concentration N1 of the oxygen in the semiconductor base body 10 is less than 1×10¹⁸ atoms/cm³. The oxygen concentration in the semiconductor base body 10 is symmetrically decreased from the position of the peak concentration N1 toward the top surface and the bottom surface of the semiconductor base body 10. The oxygen concentration around the top surface and the bottom surface of the semiconductor base body 10 is about 1×10¹⁷ atoms/cm³.

Regardless of whether the thickness T1 of the semiconductor base body 10 varies between about 200 micrometers or greater and 400 micrometers or less, the position of the peak concentration of the oxygen in the semiconductor base body 10 is substantially in the middle of the thickness T1 of the semiconductor base body 10. The thickness T1 of the semiconductor base body 10 set to about 200 micrometers or greater and 400 micrometers or less causes a variation in the position of the peak concentration of the oxygen in the semiconductor base body 10 depending on a device that executes the thermal treatment. The variation of the position of the peak concentration of the oxygen is about 50 micrometers from the middle of the thickness T1 to each of the top surface and the bottom surface. The position of the peak concentration of the oxygen is in a range of about 50 micrometers or greater and 250 micrometers or less from the top surface of the semiconductor base body 10 depending on the thickness T1 of the semiconductor base body 10 or the variation. When the thickness T1 of the semiconductor base body 10 is about 400 micrometers, for example, the position of the peak concentration of the oxygen in the semiconductor base body 10 is in a range of about 150 micrometers or greater and 250 micrometers or less from the top surface of the semiconductor base body 10. When the thickness T1 of the semiconductor base body 10 is about 200 micrometers, the position of the peak concentration of the oxygen in the semiconductor base body 10 is in a range of about 50 micrometers or greater and 150 micrometers or less from the top surface of the semiconductor base body 10.

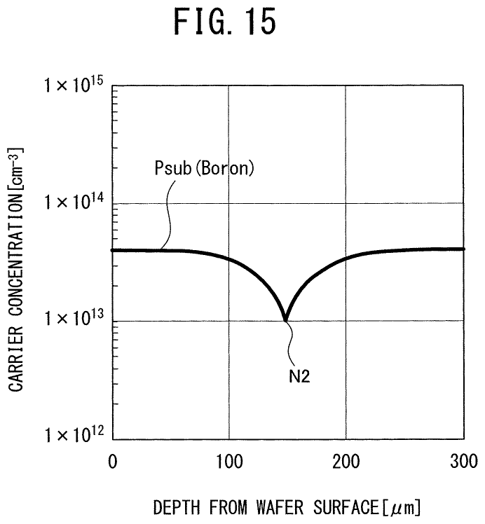

FIG. 15 is a profile of a carrier concentration in the thickness direction of the semiconductor base body 10 of the semiconductor device according to the first embodiment when the thickness T1 of the semiconductor base body 10 is set to 300 micrometers. The concentration of the p-type impurity ions is higher around the top surface and the bottom surface of the semiconductor base body 10 than the other parts, which is about 4×10¹³ cm 3. While the p-type impurity ions are offset by the oxygen turned to a thermal donor in a part of about 150 micrometers from the top surface of the semiconductor base body 10, the N-inversion can be avoided and the minimum value N₂ of the p-type impurity concentration is about 1×10¹³ cm⁻³. The position of the minimum value N₂ of the p-type impurity concentration corresponds to the position of the peak concentration N1 of the oxygen in the semiconductor base body 10 illustrated in FIG. 14.

As described above, the semiconductor device according to the first embodiment and the method of manufacturing the same can decrease the peak concentration of the oxygen in the semiconductor base body 10, so as to avoid a shift of the oxygen to a thermal donor. This can suppress the N-inversion or the increase in the specific resistance even in a deep region of the semiconductor base body 10, so as to avoid a cause of a breakdown-voltage decreasing mode derived from a shift of the oxygen to a donor that could be caused in the high-voltage power IC.

In addition, since the use of the semiconductor substrate 1 grown by the CZ method can also avoid the breakdown-voltage decreasing mode derived from a shift of the oxygen to a donor that could be caused in the high-voltage power IC, the conventional MCZ method, which inevitably requires high initial running costs regarding facility aspects, does not need to be used, so as to obtain the high-voltage power IC through the substrate production process having a high supplying ability with low costs.

### Second Embodiment

A method of manufacturing a semiconductor device according to a second embodiment differs from the method of manufacturing the semiconductor device according to the first embodiment in slicing up the silicon single crystals grown by the CZ method into a thickness of greater than 400 micrometers to cut out the semiconductor substrate 1, growing the epitaxial growth layer 2 on the top surface of the semiconductor substrate 1, and then grinding the semiconductor substrate 1 from the bottom surface side so as to lead the semiconductor base body 10 to have a thickness as thin as about 400 micrometers or less.

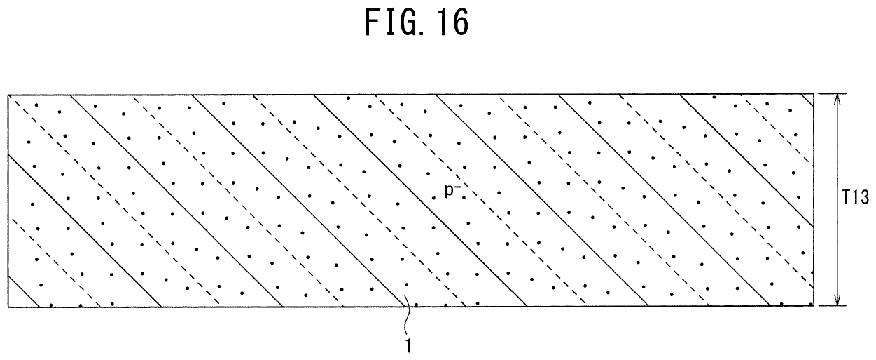

In particular, the method of manufacturing the semiconductor device according to the second embodiment slices the silicon single crystals grown by the CZ method into a thickness T13 that is greater than 400 micrometers to cut out the semiconductor substrate 1, as illustrated in FIG. 16. The thickness T13 of the semiconductor substrate 1 is in a range of about 615 micrometers or greater and 720 micrometers or less, for example.

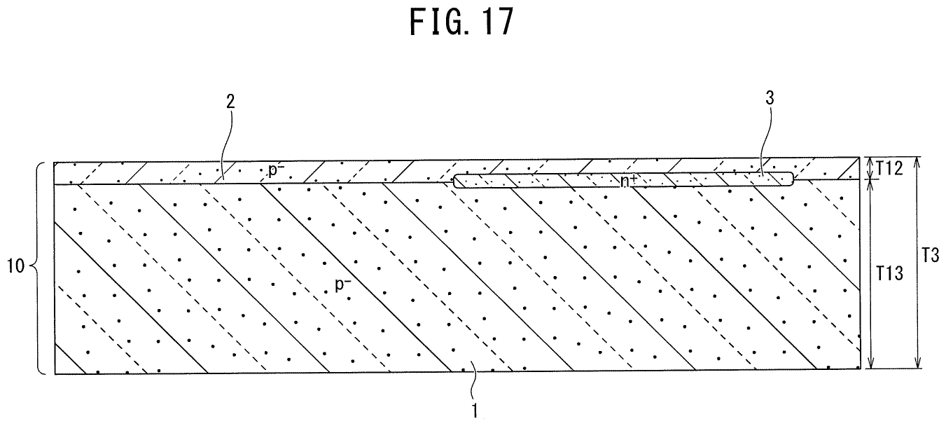

Next, the epitaxial growth layer 2 with the thickness T12 in the range of about 5 micrometers or greater and 10 micrometers or less is grown on the top surface of the semiconductor substrate 1, and the n⁺-type buried layer 3 is formed between the semiconductor substrate 1 and the epitaxial growth layer 2, so as to form the semiconductor base body 10, as illustrated in FIG. 17, in the same manner as the process of the method of manufacturing the semiconductor device according to the first embodiment. The thickness T3 of the semiconductor base body 10 is greater than 400 micrometers. For example, the thickness T3 of the semiconductor base body 10 is about 625 micrometers when the diameter of the semiconductor base body 10 is 150 millimeters, and the thickness T3 is about 725 micrometers when the diameter of the semiconductor base body 10 is 200 millimeters.

Next, the semiconductor substrate 1 is ground from the bottom surface side by back-grinding (BG) or the like, which differs from the process of the method of manufacturing the semiconductor device according to the first embodiment. This process leads the thickness T1 of the semiconductor base body 10 to be as thin as about 200 micrometers or greater and 400 micrometers or less, as illustrated in FIG. 4. The process of grinding the semiconductor substrate 1 from the bottom surface side may be executed in the substrate production process, or may be executed in the manufacturing line after sending to the FEOL. The subsequent steps of the method of manufacturing the semiconductor device according to the second embodiment are substantially the same as those of the method of manufacturing the semiconductor device according to the first embodiment, and overlapping explanations are not repeated below.

The configuration of the semiconductor device according to the second embodiment manufactured by the manufacturing method according to the second embodiment is substantially the same as that of the semiconductor device according to the first embodiment illustrated in FIG. 1, and overlapping explanations are not repeated below. The profile of the oxygen concentration in the semiconductor device according to the second embodiment is common to that shown in FIG. 14, and the profile of the carrier concentration in the semiconductor device according to the second embodiment is common to that shown in FIG. 15.

The configuration according to the second embodiment can decrease the peak concentration of the oxygen in the semiconductor base body 10, so as to avoid a shift of the oxygen to a thermal donor. This configuration can suppress the N-inversion or the increase in the specific resistance even in a deep region of the semiconductor base body 10, so as to avoid a cause of the breakdown-voltage decreasing mode derived from a shift of the oxygen to a donor that could be caused in the high-voltage power IC.

### Third Embodiment

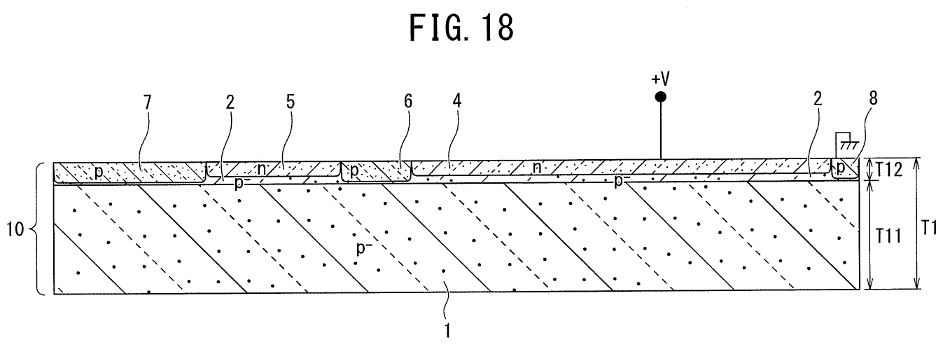

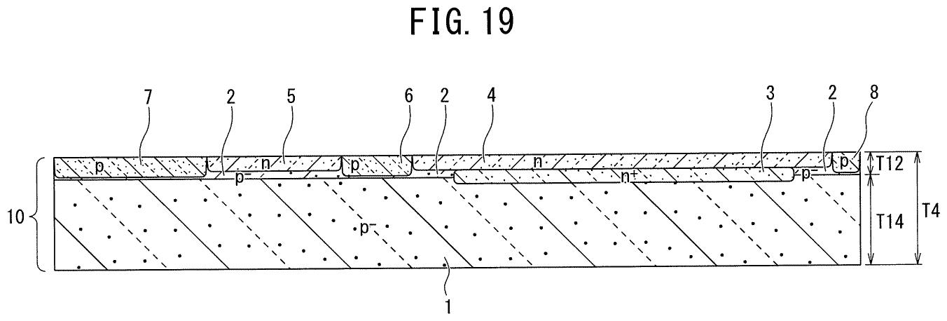

A semiconductor device according to a third embodiment differs from the semiconductor device according to the first embodiment illustrated in FIG. 1 in including the semiconductor base body (also referred to as an “epitaxial substrate”) 10 not provided with the n⁺-type buried layer between the semiconductor substrate 1 and the epitaxial growth layer 2, as illustrated in FIG. 18. The semiconductor device according to the third embodiment is used for a case in which no outside noise enters, for example. The other structures of the semiconductor device according to the third embodiment are substantially the same as those of the semiconductor device according to the first embodiment illustrated in FIG. 1, and overlapping explanations are not repeated below. The profile of the oxygen concentration in the semiconductor device according to the third embodiment is common to that shown in FIG. 14, and the profile of the carrier concentration in the semiconductor device according to the third embodiment is common to that shown in FIG. 15.

A method of manufacturing the semiconductor device according to the third embodiment differs from the method of manufacturing the semiconductor device according to the first embodiment in slicing up the silicon single crystals grown by the CZ method to cut out the semiconductor substrate 1 and then growing the epitaxial growth layer 2 on the top surface of the semiconductor substrate 1 without executing the process of either photolithography or ion implantation for forming the n⁺-type buried layer. The other processes of the method of manufacturing the semiconductor device according to the third embodiment are substantially the same as those of the method of manufacturing the semiconductor device according to the first embodiment, and overlapping explanations are not repeated below.

The configuration according to the third embodiment can decrease the peak concentration of the oxygen in the semiconductor base body 10, so as to avoid a shift of the oxygen to a thermal donor. This configuration can suppress the N-inversion or the increase in the specific resistance even in a deep region of the semiconductor base body 10, so as to avoid a cause of the breakdown-voltage decreasing mode derived from a shift of the oxygen to a donor that could be caused in the high-voltage power IC.

### Fourth Embodiment

A method of manufacturing a semiconductor device according to a fourth embodiment differs from the method of manufacturing the semiconductor device according to the first embodiment in further including a process of grinding the semiconductor substrate 1 from the bottom surface side by back-grinding (BG) or the like to further decrease the thickness after the manufacturing process including the first thermal treatment and the second thermal treatment having the same processes as in the method of manufacturing the semiconductor device according to the first embodiment. The other processes of the method of manufacturing the semiconductor device according to the fourth embodiment are substantially the same as those of the method of manufacturing the semiconductor device according to the first embodiment, and overlapping explanations are not repeated below.

The semiconductor device according to the fourth embodiment manufactured by the manufacturing method according to the fourth embodiment includes the semiconductor base body 10 having a thickness T4 that is thinner than the thickness T1 of the semiconductor base body 10 in the semiconductor device according to the first embodiment illustrated in FIG. 1, since the semiconductor substrate 1 is ground from the bottom to have a smaller thickness T14, as illustrated in FIG. 19. The thickness T4 of the semiconductor base body 10 is in a range of about 200 micrometers or greater and 280 micrometers or smaller, for example. The other structures of the semiconductor device according to the fourth embodiment are substantially the same as those of the semiconductor device according to the first embodiment illustrated in FIG. 1, and overlapping explanations are not repeated below.

The profile of the oxygen concentration in the semiconductor device according to the fourth embodiment is similar to the profile shown in FIG. 14 eliminating the region in which the thickness of the bottom surface side of the semiconductor substrate 1 is decreased. The profile of the oxygen concentration in the semiconductor device according to the fourth embodiment has a peak concentration of the oxygen that is located toward the bottom surface side below the middle. The profile of the carrier concentration in the semiconductor device according to the fourth embodiment is similar to the profile shown in FIG. 15 eliminating the region in which the thickness of the bottom surface side of the semiconductor substrate 1 is decreased.

The configuration according to the fourth embodiment can decrease the peak concentration of the oxygen in the semiconductor base body 10, so as to avoid a shift of the oxygen to a thermal donor. This configuration can suppress the N-inversion or the increase in the specific resistance even in a deep region of the semiconductor base body 10, so as to avoid a cause of the breakdown-voltage decreasing mode derived from a shift of the oxygen to a donor that could be caused in the high-voltage power IC.

### OTHER EMBODIMENTS

As described above, the invention has been described according to the first to fourth embodiments, but it should not be understood that the description and drawings implementing a portion of this disclosure limit the invention. Various alternative embodiments of the present disclosure, examples, and operational techniques will be apparent to those skilled in the art from this disclosure.

For example, while the semiconductor devices according to the first to fourth embodiments are illustrated above with the HVIC, the present disclosure can also be applied to a high-voltage power IC other than the HVIC, or to a semiconductor device, other than the high-voltage power IC, including the semiconductor base body 10 using a buried epitaxial substrate or an epitaxial substrate.

In addition, the respective configurations disclosed in the first to fourth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising a semiconductor base body including:
a semiconductor substrate of a first conductivity-type; and
an epitaxial growth layer of the first conductivity-type provided on the semiconductor substrate,
wherein the semiconductor base body has a thickness of 200 micrometers or greater and 400 micrometers or less, and
a position of a peak concentration of oxygen in the semiconductor base body is located in a depth of 50 micrometers or greater and 250 micrometers or less from a top surface of the semiconductor base body.

2. The semiconductor device of claim 1, wherein the peak concentration of the oxygen in the semiconductor base body is lower than 1×10¹⁸ atoms/cm³.

3. The semiconductor device of claim 1, wherein a concentration of the oxygen in the semiconductor base body is 1×10¹⁷ atoms/cm³ or higher and lower than 1×10¹⁸ atoms/cm³.

4. The semiconductor device of claim 1, wherein the position of the peak concentration of the oxygen in the semiconductor base body is located in a region between 50 micrometers above a middle of the thickness of the semiconductor base body toward the top surface and 50 micrometers below the middle of the thickness toward a bottom surface.

5. The semiconductor device of claim 1, wherein the position of the peak concentration of the oxygen in the semiconductor base body is located below a middle of the thickness of the semiconductor base body toward a bottom surface.

6. The semiconductor device of claim 1, wherein a position of a minimum value of a carrier concentration of the first conductivity-type in the semiconductor base body corresponds to the position of the peak concentration of the oxygen in the semiconductor base body.

7. The semiconductor device of claim 1, further comprising a buried layer of a second conductivity-type provided between the semiconductor substrate and the epitaxial growth layer.

8. A method of manufacturing a semiconductor device, comprising:
preparing a semiconductor base body having a thickness of 200 micrometers or greater and 400 micrometers or less and including a semiconductor substrate of a first conductivity-type and an epitaxial growth layer of the first conductivity-type provided on the semiconductor substrate;
decreasing a peak concentration of oxygen in the semiconductor base body by outwardly diffusing the oxygen toward a top surface and a bottom surface of the semiconductor base body by first thermal treatment; and
turning the oxygen in the semiconductor base body into a donor by second thermal treatment with the peak concentration of the oxygen in the semiconductor base body decreased.

9. The method of manufacturing the semiconductor device of claim 8, wherein the preparing the semiconductor base body prepares the semiconductor base body so as to have an oxygen concentration of 1×10¹⁸ atoms/cm³ or higher and 1.3×10¹⁸ atoms/cm³ or lower.

10. The method of manufacturing the semiconductor device of claim 8,
wherein the preparing the semiconductor base body includes:
slicing silicon single crystals grown by a Czochralski method; and
growing the epitaxial growth layer on the semiconductor substrate.

11. The method of manufacturing the semiconductor device of claim 10, wherein the preparing the semiconductor base body further includes grinding the semiconductor substrate from a bottom surface side.

12. The method of manufacturing the semiconductor device of claim 8, wherein the first thermal treatment is executed at a temperature of 1000° C. or higher and 1200° C. or lower.

13. The method of manufacturing the semiconductor device of claim 8, wherein the second thermal treatment is executed at a temperature of 350° C. or higher and 500° C. or lower.

14. The method of manufacturing the semiconductor device of claim 8, wherein the decreasing the peak concentration of the oxygen in the semiconductor base body decreases the peak concentration to lower than 1×10¹⁸ atoms/cm³.

15. A semiconductor device comprising a semiconductor base body including:
a semiconductor substrate of a first conductivity-type; and
an epitaxial growth layer of the first conductivity-type provided on the semiconductor substrate,
wherein the semiconductor base body has a thickness of 200 micrometers or greater and 400 micrometers or less, and
a position of a minimum value of a carrier concentration of the first conductivity-type in the semiconductor base body corresponds to a position of a peak concentration of oxygen in the semiconductor base body.

16. The method of manufacturing the semiconductor device of claim 8, further comprising grinding the semiconductor substrate from a bottom surface side after the turning the oxygen in the semiconductor base body into the donor.
